(19) United States
(12) Patent Application Publication
(10) Pub. No.: US 2024/0178182 A1
(43) Pub. Date: May 30, 2024

(54) APPARATUS AND METHOD FOR FLIP CHIP LASER BONDING

(71) Applicant: PROTEC CO., LTD., Gyeonggi-do (KR)

(72) Inventors: Youn Sung Ko, Gyeonggi-do (KR); GEUNSIK AHN, Seoul (KR)

(73) Assignee: PROTEC CO., LTD., Gyeonggi-do (KR)

(21) Appl. No.: 18/519,056

(22) Filed: Nov. 26, 2023

(30) Foreign Application Priority Data
Nov. 29, 2022 (KR) 10-2022-0162451

(51) Int. Cl. H01L 23/00

(52) U.S. Cl. CPC H01L 24/81; H01L 24/13; H01L 2224/13147; H01L 2224/81123; H01L 2224/8117; H01L 2224/81224

(57) ABSTRACT

A flip-chip laser bonding apparatus and method are provided in which flip-chip type semiconductor chips are bonded to a substrate using laser light. The flip-chip laser bonding apparatus and method are effective in rapidly bonding bent or flexible flip-chip type semiconductor chips to a substrate with high quality without contact defects of solder bumps.

### CROSS-REFERENCE TO RELATED APPLICATION

This application is based on and claims priority under 35 U.S.C. § 119 to Korean Patent Application No. 10-2022-0162451, filed on Nov. 29, 2022, in the Korean Intellectual Property Office, the disclosure of which is incorporated by reference herein in its entirety.

### BACKGROUND

### Technical Field

The present disclosure relates to a flip-chip laser bonding apparatus and method and, more particularly, to a flip-chip laser bonding apparatus and method for bonding flip-chip type semiconductor chips to a substrate using laser light.

### Description of Related Art

As electronic products become smaller, flip-chip type semiconductor chips using no wire bonding are widely used. A flip-chip type semiconductor chip is mounted on a substrate by forming a plurality of electrodes in the form of solder bumps on the lower surface of the semiconductor chip and bonding the electrodes at positions corresponding to solder bumps formed on the substrate.

Methods of mounting flip-chip type semiconductor chips on a substrate in this manner generally include a reflow method and a laser bonding method. In the reflow method, semiconductor chips each including fluxed solder bumps are placed on a substrate, and then the semiconductor chips are subjected to high-temperature reflow processing, thereby being bonded to the substrate. In the laser bonding method, semiconductor chips each including fluxed solder bumps are placed on a substrate as in the reflow method, and then energy is transferred to the semiconductor chips by irradiating the same with laser beams to cause the solder bumps to melt and cure instantaneously, thereby bonding the semiconductor chips to the substrate.

Flip-chip type semiconductor chips used recently are becoming thinner to tens of micrometers or less. When a semiconductor chip is this thin, the semiconductor chip is often slightly bent or warped due to internal stress in the semiconductor chip itself. When the semiconductor chip is deformed in this manner, the semiconductor chip may be bonded to the substrate, with some of the solder bumps on the semiconductor chip not contacting the corresponding solder bumps on the substrate. This situation may cause defects in the bonding process of semiconductor chips. In addition, when the temperatures of semiconductor chips and a substrate are increased to bond the semiconductor chips to the substrate, some of the semiconductor chips or a portion of the substrate may be bent or warped due to the difference in the coefficient of thermal expansion of the internal materials thereof. This phenomenon may also cause defects in the bonding process of semiconductor chips.

The reflow method has the problem of the bending of semiconductor chips due to prolonged exposure to high temperatures and the problem of low productivity due to the cooling time required for semiconductor chips.

A thermal compression (TC) bonding method includes heating and bonding semiconductor chips using a heating block. In this case, the heating method by heat conduction is used, and thus there are problems in that heating the solder takes time and the temperature of the semiconductor chip is unnecessarily increased, thereby damaging the semiconductor chip.

Accordingly, there is a need for a flip-chip bonding apparatus or a flip-chip bonding method that rapidly performs a semiconductor chip bonding process without increasing the temperature of the semiconductor chip.

### SUMMARY

The present disclosure is directed to satisfying the need as described above, and an objective of the present disclosure is to provide a flip-chip bonding apparatus and method configured to rapidly bond flip-chip type semiconductor chips to a substrate with high quality while preventing contact defects, in which the semiconductor chips are bent or warped or may be bent or warped due to increases in temperature.

Additional aspects will be set forth in part in the description which follows and, in part, will be apparent from the description, or may be learned by practice of the presented embodiments of the disclosure.

In order to satisfy the above-described need, the present disclosure provides a flip-chip laser bonding apparatus for bonding a flip-chip type semiconductor chip to a substrate using laser light, the apparatus including: a substrate support member configured to adsorb, hold, and support a lower surface of a substrate; a chip support member configured to hold and support an upper surface of the semiconductor chip; a chip transfer unit configured to transfer the chip support member relative to the substrate support member to align a position of the semiconductor chip with respect to the substrate and bring the semiconductor chip to be in contact with the substrate; and a laser head configured to bond the semiconductor chip to the substrate by irradiating the lower surface of the substrate supported on the substrate support member with laser light.

In addition, the present disclosure also provides a flip-chip laser bonding method of bonding a flip-chip type semiconductor chip to a substrate using laser light, the method including: (a) adsorbing, holding, and supporting a lower surface of a substrate by a substrate support member; (b) holding and supporting an upper surface of the semiconductor chip by a chip support member; (c) transferring the chip support member relative to the substrate support member to align a position of the semiconductor chip with respect to the substrate and bringing the semiconductor chip to be in contact with the substrate by a chip transfer unit; and (d) bonding the semiconductor chip to the substrate by irradiating the lower surface of the substrate supported on the substrate support member with laser light by a laser head.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic diagram of a flip-chip laser bonding apparatus according to an embodiment of the present disclosure;

FIGS. 2 to 4 are schematic diagrams illustrating the operation of the flip-chip laser bonding apparatus illustrated in FIG. 1; and

FIG. 5 is a flowchart for performing a flip-chip laser bonding method according to an embodiment of the present disclosure.

### DESCRIPTION OF THE EMBODIMENTS

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a flip-chip laser bonding apparatus according to the present disclosure will be described in detail with reference to the accompanying drawings.

Semiconductor chips bonded to a substrate by the flip-chip laser bonding apparatus according to the present disclosure have a concept that includes not only individual devices but also various forms of flip-chip type semiconductor components bonded to the substrate. Either a component in which individual devices are packaged or a component having the form of a multi-chip module (MCM) may also correspond to a semiconductor chip bonded to a substrate by the flip-chip laser bonding apparatus according to the present disclosure. Such a semiconductor chip and a substrate are bonded to each other by electrically connecting electrodes formed on each using solder bumps such as solder balls or copper pillars. One of a substrate and a semiconductor chip with solder bumps such as solder balls or copper pillars bonded thereto is supplied, and the solder balls or copper pillars are bonded to the other by heating pre-applied flux and solder bumps.

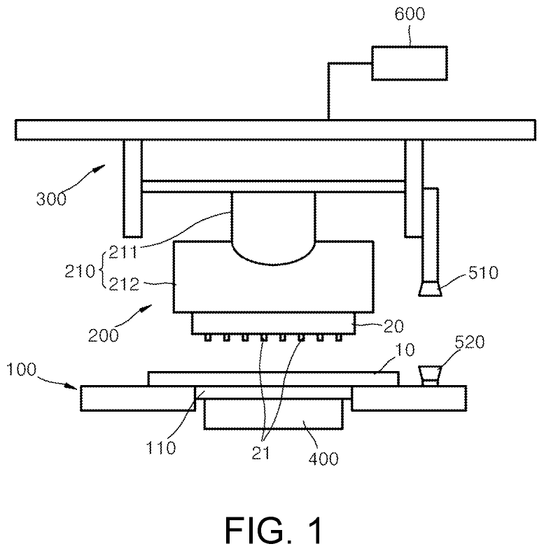

FIG. 1 is a schematic diagram of a flip-chip laser bonding apparatus according to an embodiment of the present disclosure.

As described above, solder bumps 21 such as solder balls or copper pillars are used as elements connecting a substrate 10 and a semiconductor chip 20. In the present embodiment, a case in which copper pillars are used as the solder bumps 21 will be described as an example. In addition, the copper pillars 21 may be pre-bonded to the semiconductor chip 20 or to the substrate 10, but in the present embodiment, a case in which the semiconductor chip 20 with the copper pillars 21 pre-bonded to the lower surface thereof and the fluxed substrate 10 are supplied and the semiconductor chip 20 is bonded to the substrate 10 will be described as an example.

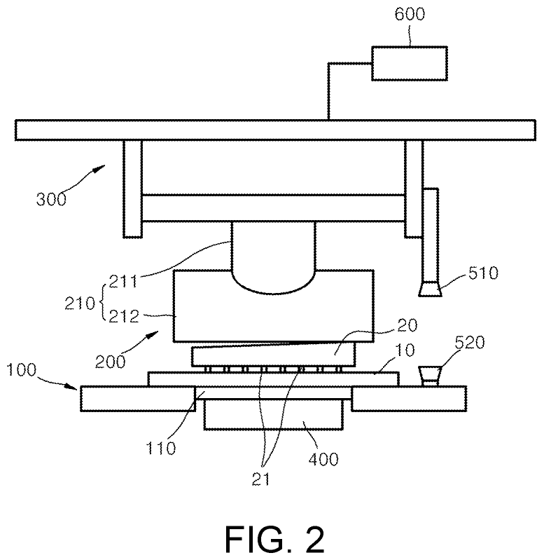

Referring to FIGS. 1 and 2, the flip-chip laser bonding apparatus according to the present embodiment includes a substrate support member 100, a chip support member 200, a chip transfer unit 300, and a laser head 400.

The substrate support member 100 adsorbs, holds, and supports the lower surface of the substrate 10. The substrate support member includes a transmission portion 110 including a transparent material. The transmission portion 110 is formed to occupy a position corresponding to at least a portion of the area of the substrate 10 and is disposed to contact the lower surface of the substrate 10. The transmission portion 110 may include a quartz material or may include a porous resin. Laser light generated by the laser head 400 irradiates the lower surface of the substrate 10 through the transmission portion 110.

The substrate support member 100 adsorbs and holds the lower surface of the substrate 10 by a vacuum adsorption method. A hole capable of transmitting negative vacuum pressure is formed in the transmission portion 110 or placed around the transmission portion 110 to adsorb the lower surface of the substrate 10. A separate substrate transfer unit may be provided to supply the substrate 10 to the substrate support member 100 and discharge the substrate 10 having the semiconductor chip 20 bonded thereto to the outside.

The chip support member 200 holds and supports the upper surface of the semiconductor chip 20 supposed to be bonded to the substrate 10. In the present embodiment, the chip support member 200 adsorbs and holds the upper surface of the semiconductor chip 20 by the vacuum adsorption method, like the substrate support member 100. The chip support member 200 may clamp and support the semiconductor chip 20 by various methods other than the vacuum adsorption method, as required.

The chip transfer unit 300 transfers the chip support member 200 with respect to the substrate support member 100 so that the position of the semiconductor chip 20 with respect to the substrate 10 may be aligned. The chip transfer unit 300 horizontally transfers the chip support member 200 back and forth and left and right and lifts the same up and down. In addition, the chip transfer unit 300 is configured to rotate the chip support member 200 within a predetermined range of angles with respect to the vertical axis in the vertical direction. With this structure, the chip transfer unit 300 adjusts the position and direction of the semiconductor chip 20 adsorbed on the chip support member 200 so that the semiconductor chip 20 is aligned with the substrate 10 supported on the substrate support member 100.

The laser head 400 irradiates the lower surface of the substrate 10 supported on the substrate support member 100 with laser light. The laser light emitted by the laser head 400 passes through the transmission portion 110 and irradiates the lower surface of the substrate 10. The laser light irradiating the substrate 10 heats the solder bumps 21 (i.e., solder balls or copper pillars) connecting the electrodes of the substrate 10 and the semiconductor chip 20 and the solder applied around the solder bumps 21, thereby bonding the semiconductor chip 20 to the substrate 10. In the present embodiment, the laser head 400 is disposed below the substrate support member 100, and emits laser light upward. In some cases, the laser head 400 may be disposed on a side or in another orientation rather than directly below the substrate support member 100. In this case, the laser head may be implemented using an optical system, such as a lens and a prism, so that the laser light irradiates the lower surface of the substrate 10 through the transmission portion 110 of the substrate support member 100. The laser head 400 generating laser light in this manner may be implemented as various types of known light sources. The laser head 400 including a VCSEL device may be used as a light source to generate laser light.

On the other hand, the flip-chip laser bonding apparatus according to the present embodiment captures images of the semiconductor chip 20 and the substrate 10 using a substrate camera 510 and a chip camera 520 to accurately align the relative positions and directions of the substrate 10 and the semiconductor chip 20. The substrate camera 510 captures the image of the upper surface of the substrate 10 placed on the substrate support member 100. The chip camera 520 captures the image of the lower surface of the semiconductor chip 20 supported on the chip support member 200. The substrate camera 510 and the chip camera 520 may be fixed in position, or the substrate camera 510 or the chip camera 520 may be disposed on a separate transfer unit to capture the image of the object while being moved. In the present embodiment, the substrate camera 510 is provided on the chip transfer unit 300 and determines the position and direction of the substrate 10 while moving with respect to the substrate 10. In addition, the substrate camera 510 is disposed in a fixed state on a side of the substrate support member 100. The chip camera 520 captures the image of the semiconductor chip 20 moving on the chip transfer unit 300 from below to determine the position and direction of the semiconductor chip 20.

The images captured by the substrate camera 510 and the chip camera 520 are transmitted to the control unit 600. The control unit 600 determines the exact relative positions of the substrate 10 and the semiconductor chip 20 using the images captured by the substrate camera 510 and the chip camera 520. The control unit 600 controls the operations of the substrate support member 100, the chip support member 200, the chip transfer unit 300, and the laser head 400. The control unit 600 operates the chip transfer unit 300 on the basis of the positions and directions of the substrate 10 and the semiconductor chip 20 to align the position and direction of the semiconductor chip 20 with respect to the substrate 10. Mass-produced semiconductor chips 20 or substrates 10 may have slightly different positions and directions, and the present disclosure may perform the alignment by determining the positions and directions of the substrates 10 and the semiconductor chips 20 each time before the bonding, thereby improving quality.

On the other hand, the chip support member 200 includes a tilting unit 210. When the chip support member 200 is lowered using the chip transfer unit 300 to contact the semiconductor chip 20 and clamp the semiconductor chip 20, the tilting unit 210 tilts in accordance with the inclination of the upper surface of the semiconductor chip 20 and starts to contact the semiconductor chip 20, as illustrated in FIG. 2. When the tilting unit 210 completely contacts the upper surface of the semiconductor chip 20, the chip support member 200 operates to adsorb and support the semiconductor chip 20.

The tilting unit 210 according to the present embodiment includes a fixed portion 211 and a contact portion 212. The fixed portion 211 is fixed to the body of the chip support member 200, and the contact portion 212 is rotatably disposed to tilt with respect to the fixed portion 211. Surfaces of the fixed portion 211 and the contact portion 212 facing each other are provided as curved surfaces to allow relative tilting. In the present embodiment, the fixed portion 211 is formed in a convex hemispherical shape, and the surface of the contact portion 212 facing the fixed portion 211 is formed in a concave hemispherical shape. Accordingly, the contact portion 212 may tilt within a predetermined range of angles along the curved surface of the contact surface with respect to the fixed portion 211. When the contact portion 212 is tilted with respect to the fixed portion 211 according to the inclination of the upper surface of the semiconductor chip 20, the tilting unit 210 maintains the tilt angle of the contact portion 212 with respect to the fixed portion 211 by a vacuum adsorption method. The above-described tilting unit 210 is generally implemented using machine parts referred to “air gyro” or “copying apparatus.” The contact portion 212 of the tilting unit 210 contacts the upper surface of the semiconductor chip 20 to adsorb and hold the upper surface of the semiconductor chip 20, and even when the semiconductor chip 20 is pressed or the height of the semiconductor chip 20 is adjusted using the chip transfer unit 300, the tilting unit 210 maintains the orientation in accordance with the inclination of the upper surface of the semiconductor chip 20.

Since the semiconductor chip 20 in the form of a multi-chip module is packaged by combining a plurality of chips, the upper surface of the semiconductor chip 20 may not be horizontal. In addition, when the internal structure of the semiconductor chip 20, such as a multi-chip module, is not uniform, the top surface of the semiconductor chip 20 may often not be a perfect hexahedron due to differences in thermal expansion caused by changes in temperature. That is, when the semiconductor chip 20 is heated during the bonding process, the upper surface of the semiconductor chip 20 may be slightly inclined. In the flip-chip laser bonding apparatus according to the present embodiment, the tilting unit 210 contacts the upper surface of the semiconductor chip 20 at an angle corresponding to the inclination of the upper surface of the semiconductor chip 20 to adjust the position and direction of the semiconductor chip 20 and uniformly press the semiconductor chip 20 while maintaining the angle of inclination, and thus there are advantages in that the position of the semiconductor chip 20 may be maintained constant, and the pressing force of the semiconductor chip 20 may be transmitted relatively uniformly. That is, when the upper surface of the semiconductor chip 20 and the contact surface of the chip support member 200 are not parallel to each other, the semiconductor chip 20 may move laterally while being pressed, but when the semiconductor chip 20 is pressed using the above-described tilting unit 210, the semiconductor chip 20 may maintain the position.

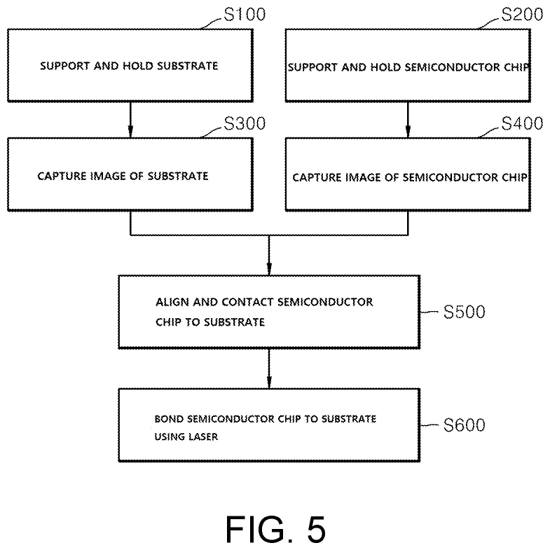

Hereinafter, an example process of performing the flip-chip laser bonding method according to the present disclosure using the flip-chip laser bonding apparatus having the above-described configuration according to the present embodiment will be described with reference to FIGS. 2 to 5. In FIGS. 2 to 4, the inclined state of the upper surface of the semiconductor chip 20 is enlarged for illustrative purposes.

When the semiconductor chip 20 is a component in which individual devices are packaged or a component such as a multi-chip module (MCM), the upper surface of the semiconductor chip 20 is often slightly inclined. In addition, since the internal material of the semiconductor chip 20 is not uniform, when the shape of the semiconductor chip 20 changes depending on the temperature due to the difference in the coefficient of thermal expansion, the upper surface of the semiconductor chip 20 may be inclined. The flip-chip laser bonding apparatus and method according to the present embodiment may align the position and direction of the semiconductor chip 20 by also taking into account the inclination of the upper surface of the semiconductor chip 20, thereby significantly improving the quality of a flip-chip bonding process.

Typically, the substrate 10 and the semiconductor chip 20 are supplied in a fluxed and temporarily mounted state. In this state, the substrate support member 100 adsorbs, holds, and supports the lower surface of the substrate 10 supplied from the outside (step (a), S100). At this time, the semiconductor chip 20 is disposed on the substrate 10.

In this state, the chip support member 200 adsorbs, holds, and supports the upper surface of the semiconductor chip 20 disposed on the substrate 10 (step (b), S200). At this time, as illustrated in FIG. 2, in response to the operation of the tilting unit 210, the contact portion 212 of the tilting unit 210 is tilted with respect to the fixed portion 211 and is tilted in accordance with the inclination of the upper surface of the semiconductor chip 20, so that the chip support member 200 adsorbs the semiconductor chip 20.

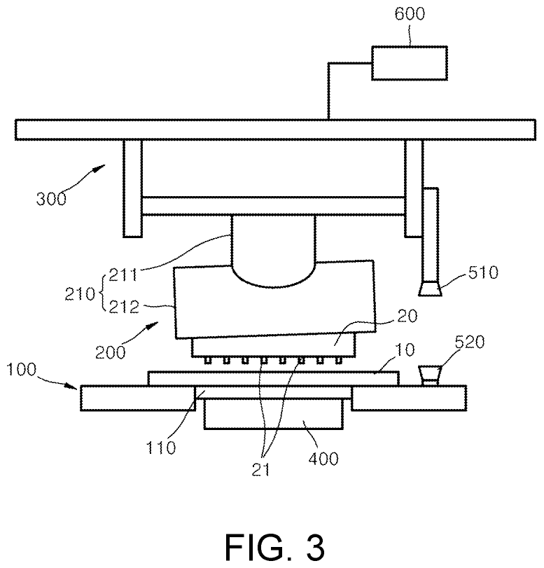

In this state, the chip transfer unit 300 as illustrated in FIG. 3 raises the chip support member 200 to lift the semiconductor chip 20 on the substrate 10. The semiconductor chip 20 is lifted, with the inclination of the upper surface of the semiconductor chip 20 maintained by the tilting unit 210.

When the chip transfer unit 300 transfers the substrate camera 510 back and forth and left and right, the substrate camera 510 moves together with the chip support member 200 and captures the image of the upper surface of the substrate 10 placed on the substrate support member 100 (step (c), S300). The image captured by the substrate camera 510 is transmitted to the control unit 600.

Afterwards, when the chip transfer unit 300 transfers the chip support member 200 back and forth and left and right, the chip camera 520 captures the image of the lower surface of the semiconductor chip 20 supported on the chip support member 200 (step (f), S400). The image captured by the chip camera 520 is transmitted to the control unit 600. Since the chip camera 520 captures the image of the lower surface of the semiconductor chip 20 in a state in which the inclination of the upper surface of the semiconductor chip 20 is maintained by the tilting unit 210 as described above, the image of the semiconductor chip 20 is captured at an inclination angle at the time of actual contact with the substrate 10. Accordingly, the chip camera 520 may capture the image of the semiconductor chip 20 to more accurately determine the position thereof.

The control unit 600 analyzes the images captured by the substrate camera 510 and the chip camera 520 to calculate the difference in the relative position and direction between the substrate 10 and the chip.

The control unit 600 operates the chip transfer unit 300 using the calculation result. The chip transfer unit 300 transfers the chip support member 200 with respect to the substrate support member 100 to align the position and direction of the semiconductor chip 20 with respect to the substrate 10. As described above, the chip transfer unit 300 has the function of rotating the semiconductor chip 20 about the vertical rotation axis, and thus the chip transfer unit 300 aligns not only the position but also the direction of the semiconductor chip 20 to complete the alignment with respect to the substrate 10.

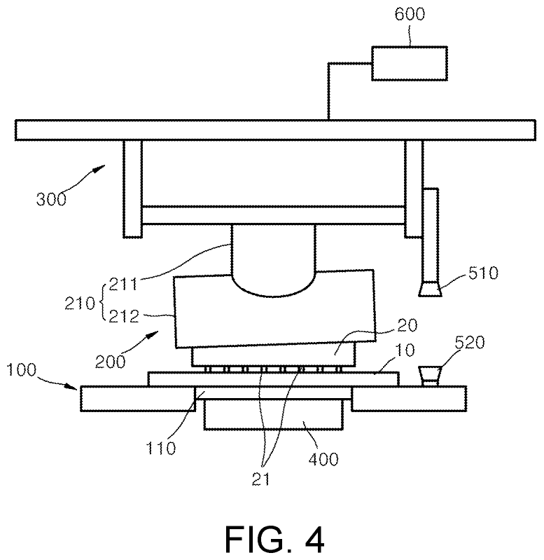

In this state, the chip transfer unit 300 lowers the chip support member 200 (step (c), S500). As illustrated in FIG. 4, the semiconductor chip 20 descends, and the copper pillars 21 contact the electrodes of the substrate 10. In this case, as described above, the tilting unit 210 also adsorbs the semiconductor chip 20 while remaining the inclination of the upper surface of the semiconductor chip 20, and the chip transfer unit 300 lowers the chip support member 200 so that the semiconductor chip 20 is pressed against the substrate 10. The chip transfer unit 300 is configured to sense and adjust the pressing force when the chip support member 200 is lowered and pressed.

While the semiconductor chip 20 is in contact with the substrate 10 in step (c) as described above, the control unit 600 operates the laser head 400 to irradiate the lower surface of the substrate 10 with laser light to bond the semiconductor chip 20 to the substrate 10 (step (d), S600).

As described above, the substrate support member 100 is provided with the transmission portion 110 including a transparent material, and thus the laser light generated by the laser head 400 passes through the transmission portion 110 and effectively transmits energy to the lower surface of the substrate 10.

Since a related-art thermal compression (TC) bonder uses a heat transfer method by conduction, there are problems in that heating the solder bumps takes time and, during the process, the temperature of the semiconductor chip 20 unnecessarily increases, thereby damaging the semiconductor chip 20. Unlike the TC bonder, the flip-chip laser bonding apparatus and method according to the present disclosure use laser light to instantaneously melt and bond the solder bumps. Therefore, the present disclosure has the advantage of not significantly increasing the temperature of the semiconductor chip 20 during the laser bonding process. In addition, the present disclosure may advantageously prevent the temperature of the semiconductor chip 20 from increasing and rapidly cool the semiconductor chip 20 by immediately blocking the laser light after the bonding is completed. Accordingly, the present disclosure may advantageously improve the quality of the bonding process of the semiconductor chip 20 while significantly increasing the operational speed.

In addition, during the laser light irradiation in step (d) as described above, the flip-chip laser bonding apparatus according to the present embodiment adjusts the pressing force on the semiconductor chip 20 and the height of the semiconductor chip 20 using the chip transfer unit 300. While the laser head 400 performs the bonding using laser light, the temperatures of the substrate 10 and the semiconductor chip 20 may increase to some extent, although not as much as in the case of the TC bonder. At this time, the substrate 10 or the semiconductor chip 20 may have warpage due to the difference in the coefficient of thermal expansion between the materials. At this time, the chip transfer unit 300 may maintain the pressing force on the semiconductor chip 20 at an appropriate level of pressing force, thereby preventing defective bonding due to deformation in the semiconductor chip 20 or the substrate 10. The substrate support member 100 and the chip support member 200 adsorb the substrate 10 and the semiconductor chip 20, respectively, and maintain vacuum pressure over large areas, thereby additionally serving to prevent the substrate 10 and the semiconductor chip 20 from warping. On the other hand, the tilting member described above also tilts at an inclination corresponding to the inclination of the upper surface of the semiconductor chip 20 and presses the entire upper surface of the semiconductor chip 20 while maintaining the tilt angle, thereby serving to prevent the semiconductor chip 20 from warping.

On the other hand, the control unit 600 may variously control the height of the semiconductor chip 20 using the chip transfer unit 300, depending on the characteristics of the copper pillars 21 disposed between the semiconductor chip 20 and the substrate 10.

First, the control unit 600 may operate the chip transfer unit 300 to maintain the pressing force on the semiconductor chip 20 constant while the laser head 400 is generating light. As the solder bumps 21 are melted by the laser light, the semiconductor chip 20 may slightly descend, and the control unit 600 may maintain the pressing force on the semiconductor chip 20 while continuing to lower the chip support member 200 by taking into account the descent of the semiconductor chip 20. The above-described method may accurately bond the semiconductor chip 20 while preventing the warpage of the semiconductor chip 20 or the substrate 10.

Second, the control unit 600 may operate the chip transfer unit 300 to maintain the height of the semiconductor chip 20 constant while the laser head 400 is generating light. The position of the semiconductor chip 20 with respect to the substrate 10 may change due to excessive pressing force, depending on the characteristics of the solder or copper pillars 21. To prepare for such a case, when the laser light starts to be emitted, the semiconductor chip 20 may not be lowered further but be maintained at the initial height, thereby allowing the solder on the substrate 10 to melt. In particular, unlike the case described and illustrated above, when the semiconductor chip 20 is bonded to the substrate 10 using conductive balls (e.g., solder balls) instead of the copper pillars 21, maintaining a constant height of the semiconductor chip 20 may be one way to achieve higher bonding quality. While the copper pillars or the solder balls are maintained at the positions of the electrodes of the substrate 10 and the semiconductor chip 20, the molten solder may realize high speed and high quality boning due to capillary action and surface tension.

Third, while the laser head 400 is generating light, the control unit 600 may operate the chip transfer unit 300 to slightly lower the height of the semiconductor chip 20 to a predetermined height and then maintain the height constant. The control unit 600 controls the lifting movement of the chip transfer unit 300 to achieve optimal quality while appropriately changing or maintaining the height of the semiconductor chip 20 according to the temperature or irradiation time of the laser light emitted by the laser head 400, depending on the characteristics of the substrate 10, the semiconductor chip 20, the solder, the copper pillars 21, or the solder balls. That is, the control unit 600 may control the chip transfer unit 300 to change or maintain the height of the chip support member 200 according to an appropriate preset profile.

By laser bonding the flip-chip type semiconductor chip 20 by various methods as described above, even when the degree of integration of the electrodes is very high and the size of the solder balls or the copper pillars 21 is very small, the flip-chip type semiconductor chip 20 may be rapidly bonded with high quality while defects are prevented.

In particular, the flip-chip laser bonding apparatus according to the present disclosure may irradiate the lower surface of the substrate 10 with laser light through the transmission portion 110 instead of irradiating the upper surface of the semiconductor chip 20 with laser light, thereby bonding the semiconductor chip 20 with high quality while minimizing breakage or thermal deformation of the semiconductor chip 20. Recently, the semiconductor chip 20 is highly integrated, such as in a multi-chip module, and is often constructed by combining different types of semiconductor devices in a single package, so when the upper surface of the semiconductor chip 20 is irradiated with laser light, the intensity of the laser light passing through the semiconductor chip 20 is not uniform depending on the location. Therefore, in this case, it is difficult to improve the quality of the laser bonding process. In contrast, when the substrate 10 is irradiated with laser light through the lower surface thereof as in the present disclosure, the substrate 10 having relatively-uniform thickness and material compared to the semiconductor chip 20 may uniformly transmit the laser light, thereby effectively melting the solder. In addition, in this case, the bonding process may only be performed using laser light at a relatively low energy level due to the relatively low thickness of the substrate 10. In addition, in this case, the energy level of the laser light transmitted to the semiconductor chip 20 is significantly lower than in other cases, and thus as an advantage, the semiconductor chip 20 may be effectively prevented from being damaged or broken during the bonding operation.

In addition, since the flip-chip laser bonding apparatus and method according to the present disclosure uses laser light as an energy source, the solder balls or the solder may be heated in a short time, and the solder balls or the solder is quickly cooled to room temperature simply by blocking the laser light source. Therefore, as an advantage, the semiconductor chip 20 may be bonded to the substrate 10 at a significantly faster speed compared to heating the semiconductor chip 20 using a heating block as in the conventional TC bonder or the like. At the same time, the time during which the semiconductor chip 20 is exposed to a temperature higher than room temperature may be minimized, and thus as an advantage, the semiconductor chip 20 may be bonded by minimizing the possibility of breakage or damage to the semiconductor chip 20.

In addition, in the flip-chip laser bonding apparatus and method according to the present disclosure, the case in which the upper surface of the semiconductor chip 20 is inclined may be taken into account, and a more accurate flip-chip bonding process may be performed by capturing the image of the semiconductor chip 20 in a state in which the angle of contact of the semiconductor chip 20 with the substrate 10 is maintained by the tilting unit 210 and pressing the semiconductor chip 20 against the substrate 10 by aligning the position and direction of the semiconductor chip 20.

The present disclosure has been described and illustrated hereinabove with respect to the exemplary embodiments, but the scope of the present disclosure is not limited to the forms described and illustrated above.

For example, the chip support member 200 has been described above as including the tilting unit 210, but in some cases, a flip-chip laser bonding apparatus may be constructed without the tilting unit 210. In this case, the chip support member adsorbs and presses the semiconductor chip 20 with a contact surface formed horizontally instead of inclined along the upper surface of the semiconductor chip 20. In addition, even when the chip support member 200 is provided with the tilting unit 210, the chip support member 200 may use a tilting unit having various structures and shapes other than those described and illustrated above.

In addition, the case in which the semiconductor chip 20 with the copper pillars 21 pre-bonded to the lower surface thereof is supplied and bonded to the substrate 10 has been described above as an example, but in contrast, the flip-chip laser bonding apparatus and method according to the present disclosure may also be used in a case in which the substrate 10 with the solder bumps pre-bonded thereto is supplied and the semiconductor chip 20 is bonded to the substrate 10. In addition, the present disclosure may be applied to a bonding process in which the electrodes of the semiconductor chip 20 and the substrate 10 are connected with solder using not only the copper pillars 21 but also conductive balls (e.g., solder balls) or similar structures as solder bumps.

In addition, the flip-chip laser bonding apparatus having a structure including the substrate camera 510 and the chip camera 520 has been described above as an example, but a flip-chip laser bonding apparatus having a structure without the substrate camera 510 or the chip camera 520 as described above may also be constructed. In this case, the positions of the substrate 10 and the semiconductor chip 20 may be measured in advance using a camera or another device, and the control unit may receive the measured values and operate the chip transfer unit 300 to align the substrate 10 and the semiconductor chip 20. In addition, the flip-chip laser bonding apparatus including the substrate camera 510 and the chip camera 520 may also be constructed by variously modifying the structures for disposing and transferring the substrate camera and the chip camera as required.

In addition, although the case in which a single semiconductor chip 20 is bonded to the substrate 10 has been described and illustrated above as an example, this is illustrated for illustrative purposes only. In most cases, the flip-chip laser bonding apparatus and the flip-chip laser bonding method according to the present disclosure are embodied such that a plurality of semiconductor chips 20 are bonded to a single substrate 10. In this case, the flip-chip laser bonding apparatus and method according to the present disclosure may be performed by bonding the plurality of semiconductor chips 20 sequentially, one by one, to the single substrate 10. In addition, in some cases, the flip-chip laser bonding apparatus and method according to the present disclosure may be constructed such that the chip support member may align the positions of the semiconductor chips 20 by adsorbing two or more semiconductor chips 20 at a time and then the semiconductor chips 20 are bonded to the substrate 10.

In addition, the substrate support member 100 has been described hereinabove as including the transmission portion 110 including a transparent material, but in some cases, the substrate support member 100 may include a translucent material and be configured to support the lower surface of the substrate 10 instead of being provided with the transmission portion 110. In this case, a portion of the laser light may still pass through the lower surface of the substrate 10 to heat the solder and enable bonding.

The flip-chip laser bonding apparatus and method according to the present disclosure are effective in rapidly bonding bent or flexible flip-chip type semiconductor chips to a substrate with high quality without contact defects of solder bumps.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A flip-chip laser bonding method of bonding a flip-chip type semiconductor chip to a substrate using a laser light, the method comprising:
a step (a) of adsorbing, holding, and supporting a lower surface of a substrate by a substrate support member;
a step (b) of holding and supporting an upper surface of the semiconductor chip by a chip support member;
a step (c) of transferring the chip support member relative to the substrate support member such that a position of the semiconductor chip is aligned with respect to the substrate and bringing the semiconductor chip to be in contact with the substrate by a chip transfer unit; and
a step (d) of bonding the semiconductor chip to the substrate by irradiating the lower surface of the substrate supported on the substrate support member with the laser light by a laser head.

2. The flip-chip laser bonding method of claim 1, wherein the step (a) is performed using the substrate support member comprising a transmission portion comprising a transparent material to transmit the laser light emitted from the laser head in the step (d) to the substrate.

3. The flip-chip laser bonding method of claim 2, wherein the step (a) is performed using the substrate support member comprising the transmission portion comprising quartz.

4. The flip-chip laser bonding method of claim 2, wherein the step (a) is performed using the substrate support member comprising the transmission portion comprising a porous resin.

5. The flip-chip laser bonding method of claim 1, wherein the step (b) comprises holding and supporting the semiconductor chip by adsorbing the upper surface of the semiconductor chip by the chip support member.

6. The flip-chip laser bonding method of claim 5, wherein the step (b) is performed using the chip support member comprising a tilting unit configured to contact the upper surface of the semiconductor chip and tilt in accordance with an inclination of the upper surface of the semiconductor chip to adsorb and support the semiconductor chip.

7. The flip-chip laser bonding method of claim 6, wherein
the step (b) comprises supporting the semiconductor chip while maintaining an angle of the tilt in accordance with the inclination of the upper surface of the semiconductor chip by the tilting unit, and
the step (c) comprises transferring the chip support member while maintaining the angle of the tilt of the semiconductor chip tilted in the step (b).

8. The flip-chip laser bonding method of claim 7, wherein the step (b) is performed using the chip support member comprising the tilting unit comprising a contact portion configured to contact and support the upper surface of the semiconductor chip and a fixed portion tiltably supporting the contact portion, wherein the fixed portion and the contact portion are configured such that surfaces thereof facing each other are curved to allow relative tilting, and an angle of the contact portion with respect to the fixed portion is maintained by pneumatic pressure.

9. The flip-chip laser bonding method of claim 1, wherein the semiconductor chip is bonded to the substrate using one of a solder ball and a copper pillar as a solder bump.

10. The flip-chip laser bonding method of claim 1, wherein each of the steps (a), (b), (c), and (d) are performed using a control unit configured to control operations of the substrate support member, the chip support member, the chip transfer unit, and the laser head.

11. The flip-chip laser bonding method of claim 10, wherein the step (c) comprises a process in which the control unit controls the chip transfer unit to adjust a height of the chip support member.

12. The flip-chip laser bonding method of claim 11, wherein the step (c) comprises a process in which the control unit operates the chip transfer unit to lower the chip support member while the step (d) is being performed.

13. The flip-chip laser bonding method of claim 11, wherein the step (c) comprises a process in which the control unit operates the chip transfer unit to maintain a height of the chip transfer unit while the step (d) is being performed.

14. The flip-chip laser bonding method of claim 11, further comprising:
a step (e) of capturing an image of the upper surface of the substrate placed on the substrate support member by a substrate camera; and
a step (f) of capturing an image of the lower surface of the semiconductor chip supported on the chip support member by a chip camera,
wherein the step (c) comprises adjusting a position and a direction of the semiconductor chip with respect to the substrate using the images captured in the steps (e) and (f).
